(19) United States
(12) Patent Application Publication
(10) Pub. No.: US 2007/0205849 A1
(43) Pub. Date: Sep. 6, 2007

(54) Frequency-selective transformer and mixer incorporating same

(76) Inventor: Brian Otis, Seattle, WA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/367,213

(22) Filed: Mar. 3, 2006

(51) Int. Cl. H03H 9/54

(52) U.S. Cl. 333/187

(57) ABSTRACT

The frequency-selective transformer comprises a capacitative transformer and an electromechanical resonator. The capacitative transformer comprises a first port, a second port, and a third port. The electromechanical resonator is connected between the second port and the third port of the capacitative transformer and has a series resonance and a parallel resonance that are closely spaced in frequency.

### BACKGROUND

In most radio frequency (RF) transmitters and receivers, the signal spectrum containing the information signal is translated to a higher frequency (upconverted) before transmission and is subsequently translated to a lower frequency (downconverted) upon reception. This is done for a variety of reasons, including a marked reduction in antenna dimensions resulting from a shorter transmission wavelength and the larger amount of bandwidth available at high transmission frequencies. Thus, frequency translation is a critical operation in most RF transmitters and receivers. Examples of such RF transmitters and receivers include radio and television transmitters and receivers, mobile telephone handsets and base stations, wireless local area network (WLAN) cards and access points and global positioning system (GPS) satellites and receivers.

In an RF receiver, frequency translation is typically accomplished by mixing the wanted RF signal output by the antenna at a frequency f_{RF} with a local oscillator signal generated by a local oscillator at a frequency f_{LO}. This results in the spectrum of the information signal carried by the wanted RF signal being shifted to an intermediate frequency (f_{IF}), where f_{IF}=|f_{RF}−f_{LO}|. In addition to the wanted RF signal at the frequency f_{RF}=|f_{LO}+f_{IF}| generating an IF signal at the frequency f_{IF}, an image signal at the so-called image frequency f_{IM}=|f_{LO}−f_{IF}| will also generate an IF signal at the frequency f_{IF}. Alternatively, the frequency f_{RF} of the wanted RF signal may be |f_{Lo}−f_{IF}| and the frequency f_{IM} of the image signal may be |f_{LO}+f_{IF}|. A receiver tuned to receive the wanted RF signal transmitted at the frequency f_{RF} will in addition receive any signal transmitted at the image frequency f_{IM}, where the frequencies of the wanted RF signal and the image signal are related by: |f_{RF}−f_{IM}|=2f_{IF}. To prevent the image signal from causing interference at the receiver, the image frequency must be greatly attenuated prior to the mixer.

In an RF transmitter, frequency translation is typically accomplished by mixing an

intermediate-frequency (IF) signal at a frequency f_{IF} with a local oscillator signal generated by a local oscillator at a frequency f_{LO}. This results in the spectrum of the information signal carried by the IF signal being shifted upwards to two radio frequencies, a wanted RF signal at a frequency (f_{RF}), where f_{RF}=|f_{LO}+f_{IF}|, and an image signal at a frequency f_{IM}=|f_{LO}−f_{IF}|. Alternatively, the frequency f_{RF} of the wanted RF signal may be |f_{LO}−f_{IF}| and the frequency f_{IM} of the image signal may be |f_{LO}+f_{IF}|. The transmitted image signal will cause interference in receivers trying to receive a wanted RF signal transmitted at a frequency at or near the frequency of the image signal. To prevent the image signal from causing interference at the receiver, the image signal must be greatly attenuated at the output of the transmitter.

Examples of ways conventionally used to attenuate the image signal in the receiver include discrete image rejection filters, direct conversion and using a complex mixer. Discrete image rejection filters are radio-frequency notch filters or bandpass filters arranged to attenuate the image frequency before mixing takes place. However, limitations of the slope of conventional filters mean that this approach is only feasible if the intermediate frequency (f_{IF}=|f_{RF}−f_{LO}|) is relatively high. Using a high intermediate frequency increases power consumption in the baseband data conversion circuitry. In addition, discrete image rejection filters are typically fabricated from discrete components and have an input impedance and an output impedance of 50 Ω. Such filters are typically bulky and impose a substantial insertion loss on the receiver front-end.

In direct conversion, the frequency of the local oscillator is made equal to the frequency of the wanted RF signal, i.e., f_{LO}=f_{RF}. This results in an intermediate frequency of 0 Hz, and no image frequency. However, direct conversion is highly susceptible to noise created by transconductor 1/f noise coloring and DC offsets created by even-order distortion. In addition, local oscillator self-mixing causes additional DC offsets.

A complex mixer rejects the image frequency without the need to filter the incoming RF signal. A complex mixer typically involves two or four mixers driven by an in-phase (I) local oscillator signal and a quadrature (Q) local oscillator signal that are exactly 90 degrees out of phase with one another. However, this scheme requires very good gain matching between the I and Q signal paths and a very accurate 90-degree phase shifter. In practice, gain differences and phase errors usually limit the image rejection to less than 40 dB without calibration. In addition, using two or more mixers increases the noise and power consumption of the receiver.

### BRIEF DESCRIPTION OF THE DRAWINGS

FIG. 1A is a schematic drawing showing an example of an FBAR that may be used as an electromechanical resonator in a frequency-selective transformer in accordance with embodiments of the invention.

FIG. 1B is a schematic drawing showing the equivalent circuit of the FBAR shown in FIG. 1A.

FIG. 1C is a graph showing the frequency response of the modulus of the impedance |Z| of an example of the FBAR shown in FIG. 1A.

FIG. 2A is a block diagram showing an example of an unbalanced frequency-selective transformer in accordance with an embodiment of the invention.

FIG. 2B is a schematic diagram showing a practical example of an unbalanced frequency-selective transformer in accordance with an embodiment of the invention.

FIGS. 3A and 3B are graphs showing the frequency response of an example of a frequency-selective transformer in accordance with an embodiment of the invention.

FIG. 4A is a block diagram showing an example of a balanced frequency-selective transformer in accordance with an embodiment of the invention.

FIG. 4B is a schematic diagram showing a practical example of a balanced frequency-selective transformer in accordance with an embodiment of the invention.

FIG. 5A is a schematic drawing showing an example of a tunable frequency-selective transformer in accordance with an embodiment of the invention.

FIG. 5B is a graph showing the frequency response of an example of the frequency-selective transformer shown in FIG. 5A with five different values of its tuning capacitor.

FIG. 6 is a schematic drawing showing an example of a multi-band frequency-selective transformer in accordance with an embodiment of the invention.

FIG. 7A is a schematic diagram showing an example of a frequency-selective transformer in accordance with another embodiment of the invention.

FIG. 7B is a graph showing the frequency response of an example of the frequency-selective transformer shown in FIG. 7A.

FIG. 8A is a schematic drawing showing an example of an unbalanced mixer in accordance with an embodiment of the invention.

FIG. 8B is a schematic drawing showing an example of an unbalanced mixer in accordance with another embodiment of the invention.

FIG. 9A is a schematic drawing showing an example of a balanced mixer in accordance with an embodiment of the invention.

FIG. 9B is a schematic drawing showing an example of a balanced mixer in accordance with another embodiment of the invention.

FIG. 10A is a schematic drawing showing an example of a receiver in accordance with an embodiment of the invention.

FIG. 10B is a schematic drawing showing an example of a receiver in accordance with another embodiment of the invention.

FIG. 11A is a schematic drawing showing an example of a transmitter in accordance with an embodiment of the invention.

FIG. 11B is a schematic drawing showing an example of a transmitter in accordance with another embodiment of the invention.

### DETAILED DESCRIPTION

Embodiments of the invention provide a frequency-selective transformer that comprises a capacitative transformer and an electromechanical resonator. The capacitative transformer comprises a first port, a second port and a third port. The electromechanical resonator is connected between the second port and the third port of the capacitative transformer and has a series resonance and a parallel resonance that are closely spaced in frequency.

Embodiments of the frequency-selective transformer are bidirectional, i.e., the transformer operates as a step-up transformer in one direction of signal flow, and as a step-down transformer in the opposite direction of signal flow. This allows the frequency-selective transformer to provide, for example, in the front end of a receiver, impedance matching between the output impedance of an antenna and the greater input impedance of a mixer or a low-noise amplifier. In another example, in the output stage of a transmitter, the frequency-selective transformer can provide impedance matching between the output impedance of a power amplifier and the input impedance of an antenna. Depending on whether the output power of the power amplifier is high or low, the output impedance of the power amplifier is respectively smaller than or greater than the input impedance of the antenna.

In the frequency-selective transformer, the series resonance and the parallel resonance of the electromechanical resonator are closely spaced in frequency and collectively determine the frequency response characteristics of the frequency-selective transformer. The frequency response characteristic of the frequency-selective transformer has a pass band centered at the frequency of the parallel resonance of the electromechanical resonator, a stop band centered at the frequency of the series resonance of the electromechanical resonator, and a relatively small frequency difference between the frequencies of the pass band and the stop band. This frequency response characteristic allows the frequency-selective transformer to provide a solution to the above-described image rejection problem and makes the frequency-selective transformer useful in many other applications. A reference in this disclosure to the frequency of a band should be taken to refer to the centerfrequency of the band.

Some embodiments of the frequency-selective transformer are unbalanced, three-terminal devices having an input terminal, an output terminal and a common terminal. Other embodiments are balanced, four-terminal devices having two input terminals and two output terminals.

An embodiment of the frequency-selective transformer suitable for incorporation into the front end of a superheterodyne receiver is configured so that the frequency of the wanted RF signal lies in the pass band of the frequency-selective transformer. The input of the frequency-selective transformer is coupled to an antenna. The output of the frequency-selective transformer and the output of a local oscillator are connected to the inputs of a mixing circuit. The local oscillator is then set to a frequency mid-way between the frequencies of the stop band and the pass band of the frequency-selective transformer. This locates the image frequency of the mixing circuit in the stop band of the frequency-selective transformer. The voltage transformation ratio of the frequency-selective transformer differs by several tens of decibels between the pass band and the stop band. This provides the receiver with a high image rejection. The mixing circuit provides an IF signal at a frequency nominally equal to one-half of the frequency difference between the pass band and the stop band of the frequency-selective transformer. Since the pass band and the stop band can be closely spaced in frequency, the frequency of the IF signal can be low, which allows the receiver to use low-power circuitry to perform baseband data conversion.

While it is hypothetically possible to use conventional capacitors and inductors to construct a frequency-selective transformer having a pass band and stop band closely spaced in frequency, in practice, the relatively low quality factor (Q) of miniature components suitable for use in modem, high density electronic circuits makes such characteristics impossible to achieve using this approach. For example, on-chip planar inductors typically have a Q of less than 20. The low Q of such components limits the achievable transformation ratio and causes the pass band and the stop band of the frequency-selective transformer to have relatively wide bandwidths and gentle side slopes. This would result in an undesirably large minimum frequency spacing between the pass band and the stop band, and the need for an undesirably high intermediate frequency with its consequent high power consumption.

Embodiments of a frequency-selective transformer in accordance with the invention incorporate an electromechanical resonator instead of a resonator fabricated using discrete capacitors and inductors. As noted above, the electromechanical resonator has a series resonance and a parallel resonance at different but closely-spaced frequencies. Electromechanical resonators having a Q of the order of 2,000 and smaller in size than a conventional planar inductor are commercially available and are relatively inexpensive. The high Q of such an electromechanical resonator results in the electromechanical resonator having narrow resonances with steep side slopes. This allows the frequency-selective transformer to have a narrow pass band and a narrow stop band closely spaced in frequency. Closely spaced means that the pass band and the stop band are spaced by less than 5% of the pass-band frequency. In typical embodiments, pass band and the stop band are spaced by about 1% of the pass-band frequency. Some electromechanical resonators have a Q sufficiently high to allow the pass band and the stop band to be spaced by as little as 0.5% of the pass-band frequency.

An electromechanical resonator can be regarded as comprising a mechanical element and a transducer. The mechanical element exhibits a mechanical resonance at the frequency of the series resonance of the electromechanical resonator. The transducer is coupled to the resonant mechanical element and converts alternating electrical energy input to the electromechanical resonator into mechanical energy. The mechanical energy output by the transducer is coupled to the mechanical element and causes the resonant mechanical element to vibrate. The parallel resonance of the electromechanical resonator is an electrical resonance between the combined capacitance of the transducer and capacitance of the circuit connected to the transducer and the inductance of the resonant mechanical element.

The electrical impedance at the input of the electromechanical resonator depends on the relationship between the frequency of the alternating electrical energy and the frequencies of the series and parallel resonances of the electromechanical resonator. The impedance is high at the frequency of the parallel resonance and is low at the frequency of the series resonance.

Various types of electromechanical resonator are possible. Examples include electrostatic, electromagnetic, piezoelectric and magnetostrictive electromechanical resonators. For example, in an electromagnetic electromechanical resonator, a ferromagnetic particle is compliantly suspended adjacent a coil. The ferromagnetic particle and its suspension constitute a mechanical element having a mechanical resonance at a frequency that depends on the mass of the ferromagnetic particle and the spring constant of the suspension. The coil and the ferromagnetic particle constitute the transducer. An electrical signal that causes current to flow through the coil generates a magnetic field that applies a mechanical force to the ferromagnetic particle. Moreover, the ferromagnetic particle moving in the proximity of the coil induces an opposing electrical signal in the coil.

In another example, an electrostatic electromechanical resonator has an electret particle compliantly suspended between the plates of a capacitor. The electret particle and its suspension constitute a mechanical element having resonant frequency that depends on the mass of the electret particle and the spring constant of the suspension. The capacitor and the electret particle constitute the transducer. An electrical signal applied between the plates of the capacitor generates an electrostatic field that applies a mechanical force to the electret particle. Moreover, the electret particle moving between the plates of the capacitor induces an opposing electrical signal across the capacitor.

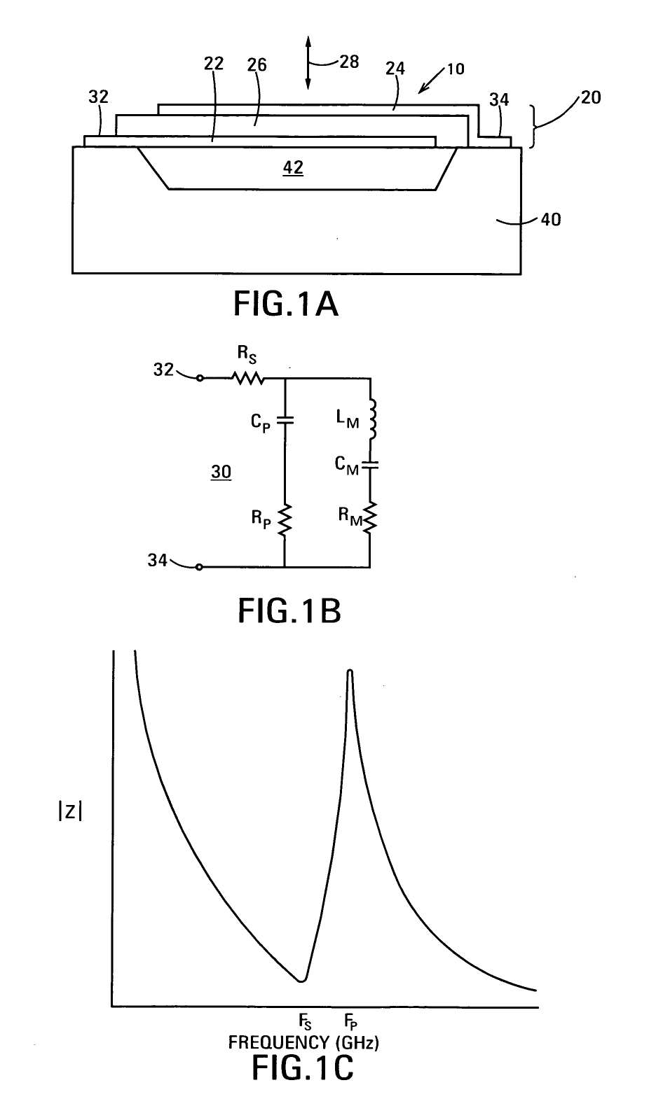

Bulk acoustic wave (BAW) resonators are known in the art and have been mass produced for use in many applications. One particular type of BAW resonator known as a film bulk acoustic resonator (FBAR) forms the basis of the duplexer used in many modem CDMA cellular telephones. An example of an FBAR will be described below with reference to FIGS. 1A-1C. The description of the FBAR also applies to electromechanical resonators based on other types of BAW resonators.

An FBAR is described in U.S. Pat. No. 5,587,620, incorporated by reference. FIG. 1A is a schematic drawing showing an example of an FBAR 10. FBAR 10 is composed of a piezoelectric resonator stack 20 and a substrate 40. Piezoelectric resonator stack 20 is composed of a planar electrode 22, a planar electrode 24 opposite planar electrode 22, and a piezoelectric element 26 located between electrodes 22 and 24. Electrical connections are made to electrodes 22 and 24 via terminals 32 and 34, respectively.

A voltage applied between electrodes 22 and 24 subjects piezoelectric element 26 to an electric field that causes piezoelectric element 26 to expand or contract in the direction orthogonal to the plane of the electrodes, as indicated by an arrow 28. Whether the piezoelectric element expands or contracts, and the magnitude of such expansion or contraction, depend on the magnitude and direction, respectively, of the electric field. Since electrodes 22 and 24 are physically attached to piezoelectric element 26, the expansion or contraction of piezoelectric element 26 causes piezoelectric resonator stack 20 to expand or contract.

When acoustically isolated from substrate 40, piezoelectric resonator stack 20 forms a high-Q electro-acoustic resonator. In the example shown, piezoelectric resonator stack 20 is acoustically isolated from substrate 40 by suspending the piezoelectric resonator stack over a cavity 42 defined in the substrate. In this example, piezoelectric resonator stack 20 contacts substrate 40 only at the periphery of piezoelectric element 26. Alternatively, piezoelectric resonator stack 20 may be acoustically isolated from substrate 40 by interposing an acoustic Bragg reflector (not shown) between electrode 22 and the major surface of the substrate, as described by Larson III et al. in U.S. patent application publication No. 2005 0 104 690, incorporated by reference.

An a.c. signal applied via terminals 32 and 34 to electrodes 22 and 24 causes piezoelectric resonator stack 20 to vibrate at the frequency of the a.c. signal. Piezoelectric resonator stack 20 has a mechanical resonance at a frequency equal to the velocity of sound in the piezoelectric resonator stack divided by twice the weighted thickness of the stack, i.e., fᵣ=c/2t₀, where fᵣ is the resonant frequency, c is the velocity of sound in the stack and t₀ is the weighted thickness of the stack. The weighted thickness of piezoelectric resonator stack 20 differs from the physical thickness of the piezoelectric resonator stack in that, in calculating the weighted thickness, the physical thickness of each layer (i.e., electrodes 22 and 24 and piezoelectric element 26) constituting the piezoelectric resonator stack is divided by the velocity of sound in the layer.

In a practical embodiment of FBAR 10 having a resonance at about 2,100 MHz, substrate 40 is part of a wafer of single-crystal silicon, piezoelectric element 26 is a layer of aluminum nitride (AIN) about 1.3 μm thick and electrodes 22 and 24 are each a layer of molybdenum about 270 nm thick. In a plane parallel to the major surface of substrate 40, electrodes 22 and 24 have an asymmetrical shape with an area of about 11,000 μm². The asymmetrical shape minimizes lateral acoustic modes in FBAR 10, as described by Larson III et al. in U.S. Pat. No. 6,215,375, incorporated by reference.

Electrodes 22 and 24 constitute a significant portion of the mass of piezoelectric resonator stack 20, so the acoustic properties of the material of the electrodes have a significant effect on the Q of the piezoelectric resonator stack. Molybdenum has acoustic properties superior to those of more typical electrode materials such as gold and aluminum. Using molybdenum as the material of electrodes 22 and 24 gives FBAR 10 higher Q than using other typical electrode materials as the material of the electrodes. Other electrode materials with superior acoustic properties include tungsten, niobium and titanium. The electrodes may have a multi-layer structure. Further details of the structure and fabrication of FBARs are disclosed by Ruby et al. in U.S. Pat. No. 6,060,818, incorporated by reference.

FIG. 1B is a schematic drawing showing an equivalent circuit 30 of FBAR 10. A shunt capacitance C_{P}, which is the capacitance of a capacitor formed by electrodes 22 and 24 and piezoelectric layer 26 as dielectric, provides the main reactive component of circuit 30. A resistor R_{P} represents the series resistance of shunt capacitance C_{P}. An inductance L_{M} and a capacitance C_{M} represent the inductance and capacitance of piezoelectric resonator stack 20. A resistor R_{M} represents loss in the piezoelectric resonator stack. A resistor R_{S} represents the series electrical resistance of the connections between terminals 32 and 34 and piezoelectric resonator stack 20.

FIG. 1C is a graph showing the frequency response of the modulus of the impedance |Z| measured between terminals 32 and 34 of an example of FBAR 10. As the frequency increases, the impedance gradually falls due to the falling impedance of shunt capacitance C_{P}. The impedance eventually reaches a minimum at the frequency F_{S} of the series resonance between mechanical inductance L_{M} and mechanical capacitance C_{M}, i.e.:

$${F}_{S} = \frac{1}{2 π \sqrt{{L}_{M} {C}_{M}}}$$

The impedance of circuit 30 then sharply increases and reaches a maximum at the frequency F_{P} of the parallel resonance between mechanical inductance L_{M} and the series combination of mechanical capacitance C_{M} and shunt capacitance C_{P}, i.e.,

$${F}_{P} = \frac{1}{2 π \sqrt{{L}_{M} \frac{{C}_{M} {C}_{P}}{{C}_{M} + {C}_{P}}}}$$

Since shunt capacitance C_{P} is typically about 20 times mechanical capacitance C_{M}, the difference between the frequency F_{S} of the series resonance and the frequency F_{P} of the parallel resonance is small.

The impedance of circuit 30 then falls steeply as the frequency increases above the frequency F_{P} of the parallel resonance.

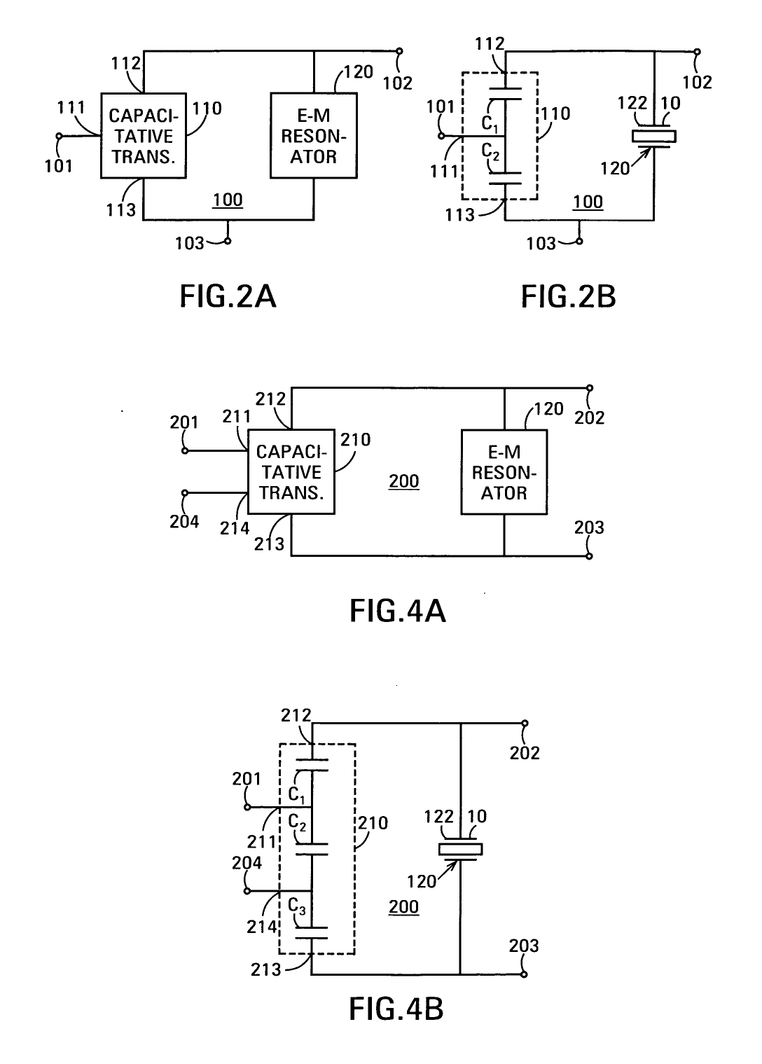

FIG. 2A is a block diagram showing an example of an unbalanced frequency-selective transformer 100 in accordance with an embodiment of the invention. A balanced example will be described below with reference to FIGS. 4A and 4B. Frequency-selective transformer 100 is composed of a capacitative transformer 110 and an electromechanical resonator 120. Capacitative transformer 110 has a first port 111, a second port 112 and a third port 113. Electromechanical resonator 120 is connected between the second port 112 and the third port 113 of capacitative transformer 110. Electromechanical resonator 120 has a series resonance and a parallel resonance closely spaced in frequency, as exemplified by the series resonance and the parallel resonance of FBAR 10 described above with reference to FIGS. 1A-1C.

Frequency-selective transformer 100 is a three-terninal device. Terminals 101, 102 and 103 are shown. Terminal 101 is connected to the first port 111 of capacitative transformer 110, terminal 102 is connected to the second port 112 of capacitative transformer 110 and to one end of electromechanical resonator 120, and terminal 103 is connected to the third port 113 of capacitative transformer 110 and to the other end of electromechanical resonator 120. In an application in which frequency-selective transformer 100 is used as a step-up transformer, terminal 101 is the input terminal and terminal 102 is the output terminal of the frequency-selective transformer. In an application in which frequency-selective transformer is used as a step-down transformer, terminal 102 is the input terminal and terminal 101 is the output terminal of the frequency-selective transformer. Terminal 103 is the signal ground terminal.

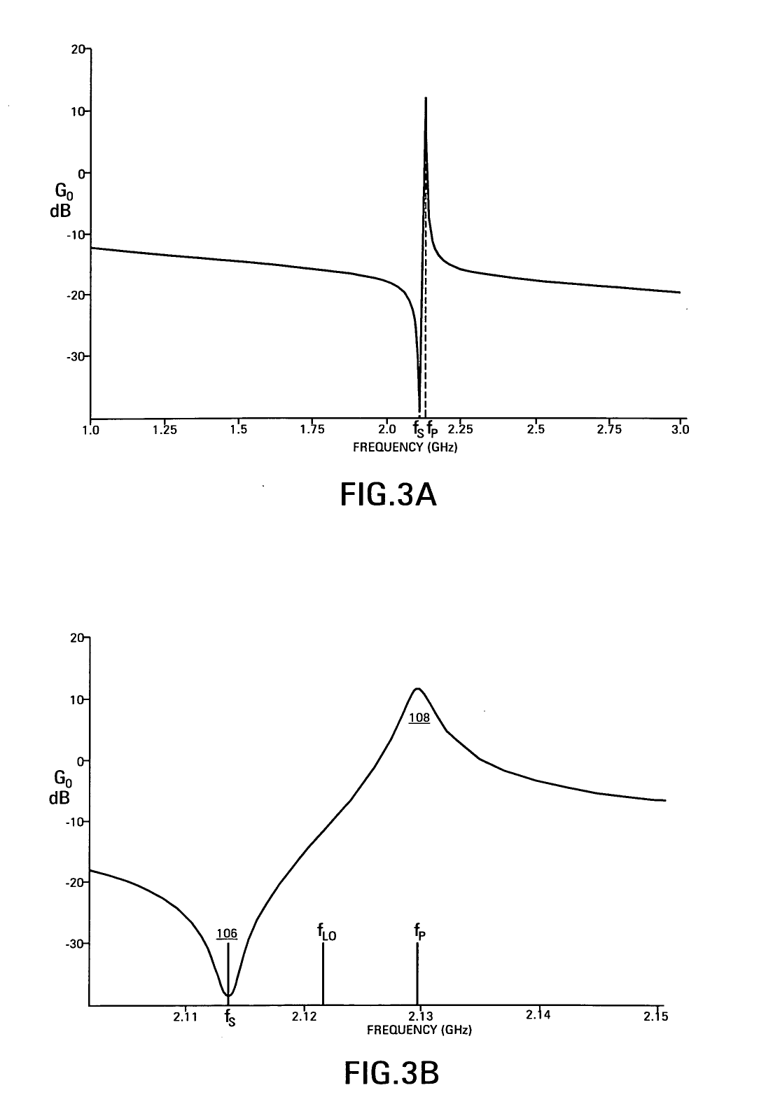

In an example in which frequency-selective transformer 100 is used as a step-up transformer, an input signal is applied between terminals 101 and 103, and frequency-selective transformer 100 provides an output signal between terminals 102 and 103. In the pass band of frequency-selective transformer 100, the output impedance between terminals 102 and 103 is greater than the input impedance between terminals 101 and 103 by a ratio that depends on the impedance transformation ratio of capacitative transformer 110. In an example in which frequency-selective transformer 100 is used as a step-down transformer, an input signal is applied between terminals 102 and 103, and frequency-selective transformer 100 provides an output signal between terminals 101 and 103. In the pass band of frequency-selective transformer 100, the output impedance between terminals 101 and 103 is smaller than the input impedance between terminals 102 and 103 by a ratio that depends on the impedance transformation ratio of capacitative transformer 110. The frequency response of frequency-selective transformer 100 and its dependence on the resonances of electromechanical resonator 120 will be described below with reference to FIGS. 3A and 3B.

FIG. 2B is a schematic diagram showing a practical example of unbalanced frequency-selective transformer 100 in accordance with an embodiment of the invention. In frequency-selective transformer 100, capacitative transformer 110 is composed of a capacitative element C₁ and a capacitative element C₂, and electromechanical resonator 120 is embodied as a bulk acoustic wave (BAW) resonator 122. In capacitative transformer 110, capacitative element C₁ and capacitative element C₂ are connected in series between second port 112 and third port 113, and the node between capacitative elements C₁ and C₂ is connected to first port 111. In the example shown in FIG. 2B, conventional capacitors are used as capacitative elements C₁ and C₂, and FBAR 10 described above with reference to FIGS. 1A-1C is used as BAW resonator 122. Another type of electromechanical resonator that may be used as electromechanical resonator 120 is a dielectric resonator, such as one of the dielectric resonators sold by First Technology, Southfield, Mich. Such dielectric resonator is not itself electrically connected to capacitative transformer 130, but instead is electromagnetically coupled to capacitative transformer 130 by locating it in a cavity electrically connected to capacitative transformer 130.

In the example shown, connecting capacitative transformer 110 in parallel with FBAR 10 decreases the frequency F_{P} of the parallel resonance of FBAR 10. Consequently, the frequency f_{P} of the pass band of frequency-selective transformer 100 is less than frequency F_{P}. Referring additionally to FIG. 1B, connecting capacitative transformer 110 in parallel with FBAR 10 connects the series combination of capacitative elements C₁ and C₂ in parallel with the shunt capacitance C_{P} of FBAR 10. Since shunt capacitance C_{P} in part determines the frequency F_{P} of the parallel resonance of FBAR 10, connecting capacitative transformer 110 in parallel with FBAR 10 reduces the frequency F_{P}. The resulting frequency f_{P} of the pass band of frequency-selective transformer 100 is given by:

$${f}_{P} = \frac{1}{2 π \sqrt{{L}_{M} \frac{{C}_{M} ( {C}_{P} + {C}_{S} )}{{C}_{M} + {C}_{P} + {C}_{S}}}}$$

where C_{S} is the capacitance of the series combination of capacitative elements C₁ and C₂, i.e.:

$${C}_{S} = \frac{{C}_{1} {C}_{2}}{{C}_{1} + {C}_{2}} .$$

Connecting capacitative transformer 110 in parallel with FBAR 10 to form frequency-selective transformer 100 leaves the frequency F_{S} of the series resonance of FBAR 10 unchanged. Thus, the frequency fₛ of the stop band of frequency-selective transformer 100 is the same as the frequency FS of the series resonance of FBAR 10 in isolation.

In capacitative transformer 110, capacitative element C₂ is typically larger in capacitance than capacitative element C₁. Consequently, the impedance Z₂ between ports 112 and 113 is greater than the impedance Z₁ between ports 111 and 113 by a ratio that depends on the capacitances of capacitative elements C₁ and C₂. In the pass band of frequency-selective transformer 100, the impedance presented by electromechanical resonator 120 between the second port 112 and third port 113 of capacitative transformer 110 is very high, as shown in FIG. 1C. Consequently, in frequency-selective transformer 100, the impedance between ports 112 and 113 is the impedance of the source resistance between terminals 101 and 103 reflected through capacitive transformer 110. The impedance Z₂ between terminals 102 and 103 is therefore greater than the impedance Z₁ between terminals 101 and 103. The impedance transformation ratio Z₂/Z₁ of frequency-selective transformer 100 is given by:

$$\frac{{Z}_{2}}{{Z}_{1}} = {( \frac{{C}_{1} + {C}_{2}}{{C}_{1}} )}^{2} ,$$

where C₁ and C₂ are the capacitances of capacitative elements C₁ and C₂, respectively.

In the pass band of frequency-selective transformer 100, the voltage V₂ between terminals 102 and 103 is also greater than the voltage V₁ between terminals 101 and 103. The voltage transformation ratio V₂/V₁ of frequency-selective transformer 100 in its pass band is given by:

$$\frac{{V}_{2}}{{V}_{1}} = \frac{{C}_{1} + {C}_{2}}{{C}_{1}} .$$

At the frequency f_{S} of the stop band of frequency-selective transformer 100, i.e., at the frequency F_{S} of the series resonance of FBAR 10, the impedance presented by FBAR 10 between the second port 112 and third port 113 of capacitative transformer 110 is very low, as shown in FIG. 1C. Thus, at the stop band frequency f_{S}, FBAR 10 presents substantially a short circuit between second port 112 and third port 113, the impedance and voltage between ports 112 and 113 is very low, and the voltage transformation ratio between terminal 101 and terminal 102 of frequency-selective transformer 100 is also very low.

At frequencies outside its pass band and its stop band, frequency-selective transformer 100 functions as a capacitive load between terminal 101 and terminal 102. At such frequencies, FBAR 10 appears principally as shunt capacitance C_{P} (FIG. 1B) connected in parallel with ports 112 and 113 of capacitative transformer 110. Shunt capacitance C_{P} of FBAR 10 and the capacitative element C₁ of capacitative transformer 110 collectively form a capacitative voltage divider having an input at terminal 101 and an output at terminal 102.

FIGS. 3A and 3B are graphs showing the frequency response of an exemplary embodiment of unbalanced frequency-selective transformer 100 described above with reference to FIG. 2B. The frequency response of unbalanced frequency-selective transformer 100 described above with reference to FIG. 2A is similar, as are the frequency responses of the embodiments that will be described below with reference to FIGS. 4A and 4B. The frequency responses shown in FIGS. 3A and 3B show the frequency dependence of the voltage transformation ratio G₀ (expressed in decibels (dB)) between the output signal output between terminals 102 and 103 and an input signal applied between terminals 101 and 103. FIG. 3B has an expanded frequency scale to enable the pass band 106 and the stop band 108 of the frequency-selective transformer to be depicted more clearly.

At input signal frequencies below the frequency f_{S} of the stop band of frequency-selective transformer 100, the capacitance of FBAR 10 and the capacitative element C₁ of capacitative transformer 110 form a capacitative divider. As a result, the voltage transformation ratio of frequency-selective transformer 100 between terminals 101 and 103 and terminals 102 and 103 is less than unity. In this frequency range, the voltage transformation ratio remains relatively constant with frequency, as shown.

As the frequency of the input signal applied between terminals 101 and 103 approaches the stop band 106 of frequency-selective transformer 100, the impedance of FBAR 10 sharply falls, as described above. This sharply increases the attenuation of the input signal by FBAR 10, and sharply decreases the voltage transformation ratio of frequency-selective transformer 100. At the center frequency f_{S} of stop band 106, i.e., at the frequency of the series resonance of FBAR 10, the impedance of the FBAR is very low, and the attenuation of the input signal by FBAR 10 is a maximum. The voltage transformation ratio of frequency-selective transformer 100 is therefore very low with respect to input signals, such as image signals, at frequencies within stop band 106. The stop band 106 of frequency-selective transformer 100 can be regarded as encompassing a range of frequencies in which the voltage transformation ratio of frequency-selective transformer 100 is within a specified ratio, e.g., 3 dB, of the minimum voltage transformation ratio.

As the frequency of the input signal increases above the stop band 106 of frequency-selective transformer 100, the impedance of FBAR 10 sharply increases toward its off-resonance value and the attenuation of the input signal by FBAR 10 sharply decreases towards its off-resonance value. Then, as the frequency of the input signal approaches the pass band 108 of frequency-selective transformer 100, the impedance of FBAR 10 sharply increases, as described above, which sharply increases the voltage transformation ratio of frequency-selective transformer 100. Closer to pass band 108, the impedance of FBAR 10 increases to a point at which the voltage transformation ratio of frequency-selective transformer 100 becomes greater than unity, i.e., frequency-selective transformer 100 becomes a step-up transformer.

At the center frequency f_{P} of pass band 108, i.e., the frequency of the parallel resonance of FBAR 10, the impedance of the FBAR is very high, and the voltage transformation ratio of frequency-selective transformer 100 reaches a maximum. The maximum voltage transformation ratio is determined by the voltage transformation ratio of capacitative transformer 110, as described above. Frequency-selective transformer 100 therefore has a significant voltage transformation ratio with respect to input signals, such as wanted RF signals, at frequencies within pass band 108. The pass band 108 of frequency-selective transformer 100 can be regarded as encompassing a range of frequencies in which the voltage transformation ratio of the frequency-selective transformer is within a specified ratio, e.g., 3 dB, of the maximum voltage transformation ratio.

As the frequency of the input signal increases above pass band 108, the impedance of FBAR 10 sharply decreases, the attenuation of the input signal by FBAR 10 sharply increases towards its off-resonance value, and the voltage transformation ratio of frequency-selective transformer 100 sharply decreases towards its off-resonance value.

FIG. 4A is a block diagram showing an example of a balanced frequency-selective transformer 200 in accordance with an embodiment of the invention. Frequency-selective transformer 200 is composed of a capacitative transformer 210 and electromechanical resonator 120. Capacitative transformer 210 has a first port 211, a second port 212, a third port 213 and a fourth port 214. Electromechanical resonator 120 is connected between the second port 212 and the third port 213 of capacitative transformer 210. Electromechanical resonator 120 has a series resonance and a parallel resonance closely spaced in frequency, as described above.

Frequency-selective transformer 200 is a bidirectional, four-terminal device. Terminals 201, 202, 203 and 204 are shown. Terminal 201 is connected to the first port 211 of capacitative transformer 210, terminal 202 is connected to the second terminal 212 of capacitative transformer 210 and to one end of electromechanical resonator 120, terminal 203 is connected to the third port 213 of capacitative transformer 210 and to the other end of electromechanical resonator 120, and terminal 204 is connected to the fourth port 214 of capacitative transformer 210.

In an example in which frequency-selective transformer 200 is used as a step-up transformer, an input signal is applied between terminals 201 and 204, and frequency-selective transformer 200 provides an output signal between terminals 202 and 203. In the pass band of frequency-selective transformer 200, the output impedance between terminals 202 and 203 is greater than the input impedance between terminals 201 and 204 by a ratio that depends on the impedance transformation ratio of capacitative transformer 210. In an example in which frequency-selective transformer 200 is used as a step-down transformer, an input signal is applied between terminals 202 and 204, and frequency-selective transformer 200 provides an output signal between terminals 201 and 204. In the pass band of frequency-selective transformer 200, the output impedance between terminals 201 and 204 is smaller than the input impedance between terminals 202 and 203 by a ratio that depends on the impedance transformation ratio of capacitative transformer 210. The frequency response of frequency-selective transformer 200 and its dependence on the resonances of electromechanical resonator 120 are similar to those described above with reference to FIGS. 3A and 3B.

FIG. 4B is a schematic diagram showing a practical example of balanced frequency-selective transformer 200 in accordance with an embodiment of the invention. In frequency-selective transformer 200, capacitative transformer 210 is composed of a capacitative element C₁, a capacitative element C₂ and a capacitative element C₃, and electromechanical resonator 120 is embodied as a bulk acoustic wave (BAW) resonator 122. In capacitative transformer 210, capacitative element C₁, capacitative element C₂ and capacitative element C₃ are connected in order in series between second port 212 and third port 213, the node between capacitative elements C₁ and C₂ is connected to first port 211 and the node between capacitative elements C₂ and C₃ is connected to fourth port 214. In the example shown in FIG. 4B, conventional capacitors are used as capacitative elements C₁, C₂ and C₃, and FBAR 10 described above with reference to FIGS. 1A-1C is used as BAW resonator 122.

In the example shown, connecting capacitative transformer 210 in parallel with FBAR 10 decreases the frequency F_{P} of the parallel resonance of FBAR 10. Consequently, the frequency f_{P} of the pass band of frequency-selective transformer 200 is less than frequency F_{P}. Referring additionally to FIG. 1B, connecting capacitative transformer 210 in parallel with FBAR 10 connects the series combination of capacitative elements C₁, C₂ and C₃ in parallel with the shunt capacitance C_{P} of FBAR 10. Since shunt capacitance C_{P} in part determines the frequency F_{P} of the parallel resonance of FBAR 10, connecting capacitative transformer 210 in parallel with FBAR 10 reduces the frequency F_{P}. The resulting frequency f_{P} of the pass band of frequency-selective transformer 200 is given by:

$${f}_{P} = \frac{1}{2 π \sqrt{{L}_{M} \frac{{C}_{M} ( {C}_{P} + {C}_{S} )}{{C}_{M} + {C}_{P} + {C}_{S}}}}$$

where C_{S} is the capacitance of the series combination of capacitative elements C₁, C₂ and C₃, i.e.:

$${C}_{S} = \frac{{C}_{1} {C}_{2}}{{C}_{1} + 2 {C}_{2}} ,$$

assuming C₃=C₁

Connecting capacitative transformer 210 in parallel with FBAR 10 to form frequency-selective transformer 200 leaves the frequency Fₛ of the series resonance of FBAR 10 unchanged. Thus, the frequency f_{S} of the stop band of frequency-selective transformer 200 is the same as the frequency F_{P} of the series resonance of FBAR 10 in isolation.

In capacitative transformer 210, capacitative element C₁ and capacitative element C₃ nominally have equal capacitances, and capacitative element C₂ is typically larger in capacitance than capacitative elements C₁ and C₃. Consequently, the impedance Z₂ between ports 212 and 213 is greater than the impedance Z₁ between ports 211 and 214 by a ratio that depends on the capacitances of capacitative elements C₁, C₂ and C₃. In the pass band of frequency-selective transformer 200, the impedance presented by electromechanical resonator 120 between the second port 212 and third port 213 of capacitative transformer 210 is very high, as shown in FIG. 1C. Consequently, in frequency-selective transformer 200, the impedance between terminals 202 and 203 is the impedance of the source resistance between terminals 201 and 204 reflected through capacitative transformer 210. The impedance Z₂ between terminals 202 and 203 is therefore greater than the impedance Z₁ between terminals 201 and 204. Assuming that capacitative elements C₁ and C₃ are equal in capacitance, the impedance transformation ratio Z₂/Z₁ of frequency-selective transformer 200 is given by:

$$\frac{{Z}_{2}}{{Z}_{1}} = {( \frac{{C}_{1} + ( {C}_{2} / 2 )}{{C}_{1}} )}^{2} .$$

In the pass band of frequency-selective transformer 200, the voltage V₂ between terminals 202 and 203 is also greater than the voltage V₁ between terminals 201 and 204. Assuming that capacitative elements C₁ and C₃ are equal in capacitance, the pass band voltage transformation ratio V₂/V₁ of frequency-selective transformer 200 is given by:

$$\frac{{V}_{2}}{{V}_{1}} = \frac{{C}_{1} + ( {C}_{2} / 2 )}{{C}_{1}} .$$

At the frequency f_{S} of the stop band of frequency-selective transformer 200, i.e., at the frequency F_{S} of the series resonance of FBAR 10, the impedance presented by FBAR 10 between the second port 212 and third port 213 of capacitative transformer 210 is very low, as shown in FIG. 1C. Thus, at the stop band frequency f_{S}, FBAR 10 presents substantially a short circuit between second port 212 and third port 213, the impedance and voltage between ports 212 and 213 is very low, and the voltage transformation ratio between terminals 201/204 and terminals 202/203 of frequency-selective transformer 200 is also very low.

At frequencies outside its pass band and its stop band, frequency-selective transformer 200 functions as a capacitive load between terminals 201/204 and terminals 202/203. At such frequencies, FBAR 10 appears principally as shunt capacitance C_{P} (FIG. 1B) connected in parallel with ports 212 and 213 of capacitative transformer 210. Shunt capacitance C_{P} of FBAR 10 and the capacitative elements C₁ and C₃ of capacitative transformer 210 collectively form a capacitative voltage divider having an input at terminals 201/204 and an output at terminals 202/203.

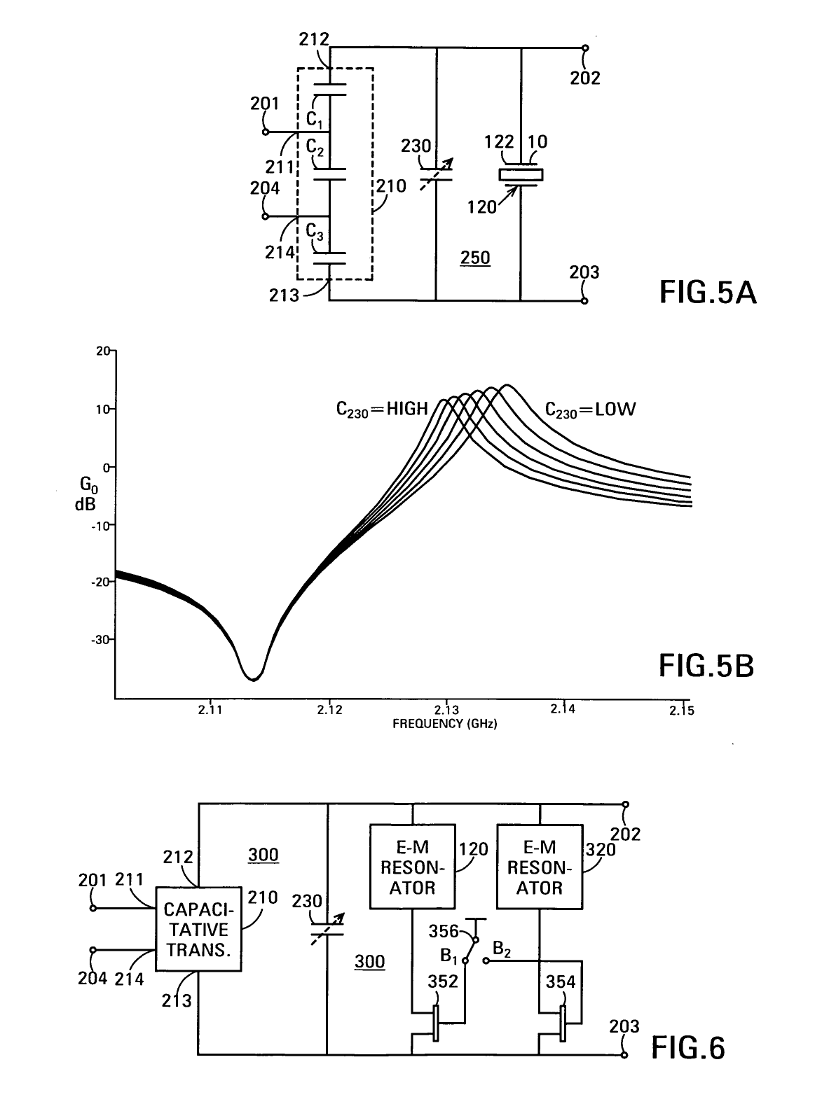

FIG. 5A is a schematic drawing showing an example of a tunable frequency-selective transformer 250 in accordance with an embodiment of the invention. Frequency-selective transformer 250 is based on frequency-selective transformer 200 described above with reference to FIG. 4B with the addition of a tuning capacitor 230 in parallel with FBAR 10. Tuning capacitor 230 is used to change the frequency f_{P} of the pass band of frequency-selective transformer 250. As noted above with reference to FIG. 2B, connecting capacitance in parallel with FBAR 10 decreases the frequency F_{P} of the parallel resonance of the FBAR. Changing the frequency of the parallel resonance of the FBAR in turn changes the frequency of the pass band of frequency-selective transformer 200.

FIG. 5B is a graph showing the frequency response of an example of frequency-selective transformer 250 with five different values C₂₃₀ of tuning capacitor 230 ranging from low to high. In some embodiments, tuning capacitor 230 is a variable capacitor that allows the frequency of the pass band of frequency-selective transformer 200 to be tuned to any frequency within a given frequency range.

Frequency-selective transformer 200 described above with reference to FIG. 4A may also be modified by connecting a tuning capacitor similar to tuning capacitor 230 in parallel with electromechanical resonator 120. Frequency-selective transformer 100 described above with reference to FIGS. 2A and 2B may be modified by connecting a tuning capacitor in parallel with electromechanical resonator 120. However, for a given capacitance of the tuning capacitor, the change in the frequency of the pass band is approximately one half in unbalanced frequency-selective transformer 100 than in balanced frequency-selective transformer 250 due to the Miller multiplication inherent in the differentially-driven balanced embodiments.

FIG. 6 is a schematic drawing showing an example of a multi-band frequency-selective transformer 300 in accordance with an embodiment of the invention. Frequency-selective transformer 300 is a multi-band frequency-selective transformer based on frequency-selective transformer 200 described above with reference to FIG. 4A. In frequency-selective transformer 300, a switch 352 is connected in series with electromechanical resonator 120. Frequency-selective transformer 300 additionally comprises a tuning capacitor 230, an additional electromechanical resonator 320 and an additional switch 354. Optional tuning capacitor 230 is connected between the ports 212 and 213 of capacitative transformer 210. Electromechanical resonator 320 and switch 354 are connected in series between ports 212 and 213.

In the example shown, switch 352 and switch 354 are embodied as respective switching transistors. The control electrodes, e.g., gates, of switches 352 and 354 are connected to respective poles of a band selector switch 356. In one position B₁ of band selector switch 356, switch 352 is activated and switch 354 is deactivated so that the frequencies of the stop band and of the pass band of frequency-selective transformer 300 are defined by the frequencies of the series resonance and the parallel resonance, respectively, of electromechanical resonator 120. In the other position B₂ of band selector switch 356, switch 354 is activated and switch 352 is deactivated so that the frequencies of the stop band and of the pass band of frequency-selective transformer 300 are defined by the frequencies of the series resonance and the parallel resonance, respectively, of electromechanical resonator 320. In embodiments in which switches 352 and 354 are implemented as CMOS transistors, each of switches 352 and 354 has an additional CMOS transistor switch (not shown) connected between its gate and ground. When switch 352 is activated, the additional CMOS transistor switch connected to the gate of switch 354 is activated to deactivate switch 354, and vice versa.

Electromechanical resonator 320 is similar to electromechanical resonator 120 but is structured so that its parallel resonance differs in frequency from that of electromechanical resonator 120. Thus, when frequency-selective transformer 300 operates with electromechanical resonator 320 activated, the frequency of its pass band differs from that when it is operated with electromechanical resonator 120 activated.

Electromechanical resonator 320 may additionally be structured so that its series resonance differs in frequency from that of electromechanical resonator 120. For example, when frequency-selective transformer 300 is connected to a mixer (not shown), as will be described in more detail below, each of electromechanical resonator 120 and electromechanical resonator 320 is structured such that its series resonance and its parallel resonance differ in frequency by twice the frequency of the intermediate frequency circuitry connected to the mixer. This way, the image frequency lies in the stop band of frequency-selective transformer 300 regardless of the setting of band selector switch 356.

Other embodiments of frequency-selective transformer have more than the two bands of the example shown FIG. 6. In such embodiments the number of electromechanical resonators and the number of poles in band selector switch 356 are each equal to the number of bands.

In the examples described above, conventional capacitors are used as the capacitative elements C₁ and C₂ of capacitative transformer 110 and the capacitative elements C₁, C₂ and C₃ of capacitative transformer 210. Other capacitative devices may alternatively be used as capacitative elements C₁, C₂ and C₃. As noted above with reference to FIGS. 1A-1C, BAW resonators are essentially capacitative at frequencies outside the frequency ranges of their series and parallel resonances. Accordingly, BAW resonators, and, specifically, FBARs, may be used as one or more of capacitative elements C₁, C₂ and C₃.

Using BAW resonators as respective capacitative elements C₁, C₂ and C₃ allows the size of the frequency-selective transformer to be reduced since the BAW resonators providing capacitative elements C₁, C₂ and C₃ can be fabricated on the same substrate and using the same processing as the BAW resonator providing electromechanical resonator 120. The capacitative elements use the same layer of piezoelectric material for their respective dielectrics as that used to provide the piezoelectric element 26 (FIG. 1A) of the BAW resonator that provides electromechanical resonator 120. The different capacitances of the capacitative elements and electromechanical resonator 120 (collectively components) are obtained simply by differences in the areas of the electrodes (corresponding to electrodes 22 and 24 of FBAR 10) of the respective components. The layers of metal that are patterned to define the electrodes of the capacitative elements and of the electromechanical resonator are additionally patterned to define electrical traces that interconnect the components to form the frequency-selective transformer.

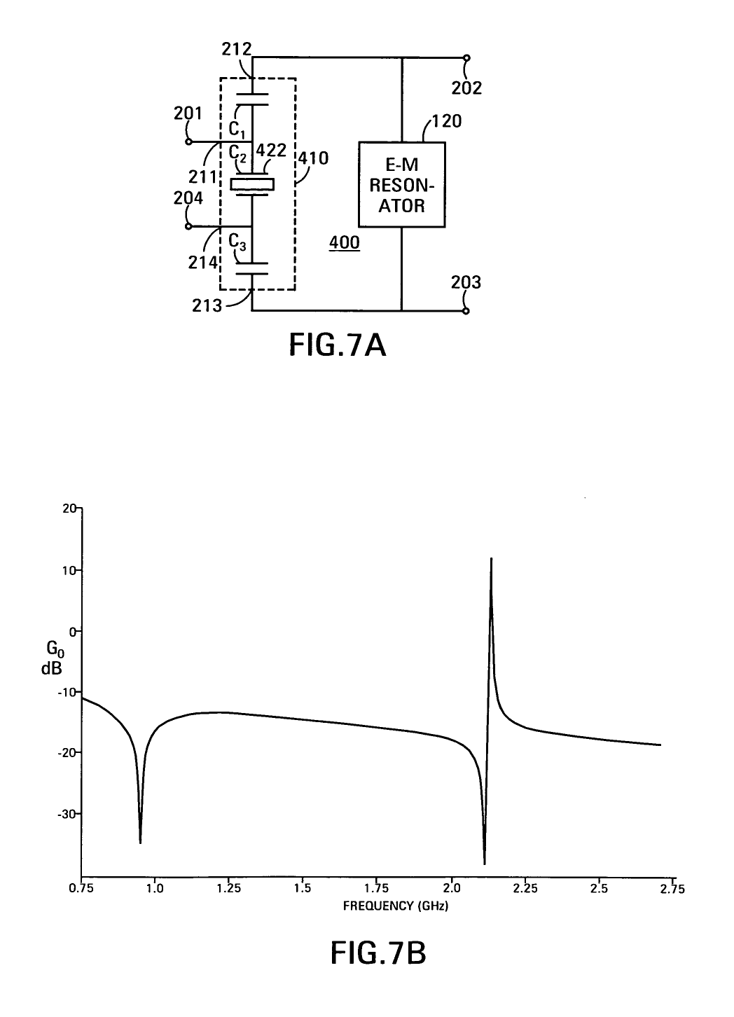

FIG. 7A is a schematic diagram showing an example of a frequency-selective transformer 400 in accordance with an embodiment of the invention. Frequency-selective transformer 400 is based on frequency-selective transformer 200 described above with reference to FIG. 4B. Frequency-selective transformer 100 described above with reference to FIG. 2B may be similarly modified.

In frequency-selective transformer 400, a BAW resonator 422 provides capacitative element C₂ in capacitative transformer 410. The series resonance of BAW resonator 422 is used to provide frequency-selective transformer 400 with additional frequency selection, specifically, an additional stop band.

In the example shown, BAW resonator 422 is structured to have its series resonance at the frequency of the additional stop band. At the frequency of the series resonance of BAW resonator 422, the impedance of BAW resonator 422 is very low, as described above. Thus, at the frequency of the series resonance, BAW resonator 422 provides a short circuit between terminal 201 and terminal 204, which significantly attenuates any signal applied between the terminals and provides frequency-selective transformer 400 with an additional stop band. At the parallel resonance of BAW resonator 422, the capacitive load presented between terminals 201/204 decreases since the capacitance of capacitative element C₂ is tuned out by BAW resonator 422. This does not significantly affect the frequency response of frequency-selective transformer 400.

Capacitative elements C₁ and C₃ are shown as conventional capacitors, but BAW resonators may alternatively be used as capacitative elements C₁ and C₃. A BAW resonator may be used as one or both of capacitative elements C₁ and C₂ in the capacitative transformer 110 of unbalanced frequency-selective transformer 100 described above with reference to FIGS. 2A and 2B. The frequencies of the pass band and the two stop bands may differ from those in this example.

FIG. 7B is a graph showing the frequency response of an example of frequency-selective transformer 400. Frequency-selective transformer 400 has a pass band in the 2.1 GHz PCS band and a stop band covering the band of image frequencies corresponding to the PCS band, as described above. Additionally, in the 900 MHz mobile band, frequency-selective transformer 400 has an additional stop band provided by the series resonance of BAW resonator 422 used as capacitative element C₂ in capacitative transformer 410. The additional stop band isolates circuitry downstream of the terminals 202/203 of frequency-selective transformer 400 from signals at frequencies in the additional stop band.

Embodiments of the invention additionally provide an unbalanced mixer comprising an unbalanced frequency-selective transformer in accordance with an embodiment of the invention, a local oscillator circuit and a mixing circuit. The mixing circuit comprises a radio-frequency (RF) port, an intermediate frequency (IF) port and a local oscillator (LO) port. The LO port is connected to the local oscillator. The frequency-selective transformer comprises a capacitative transformer and an electromechanical resonator. The capacitative transformer has a first port, a second port and a third port. The capacitative transformer is coupled to the RF port of the mixing circuit via either the first port or the second port. The electromechanical resonator is connected between the second port and the third port of the capacitative transformer. The electromechanical resonator has a series resonance and a parallel resonance that are closely spaced in frequency. In the mixer, the frequency-selective transformer operates as a step-up transformer when the capacitative transformer is coupled to the RF port of the mixing circuit via the first port. Alternatively, the frequency-selective transformer operates as a step-down transformer when the capacitative transformer is coupled to the RF port of the mixing circuit via the second port.

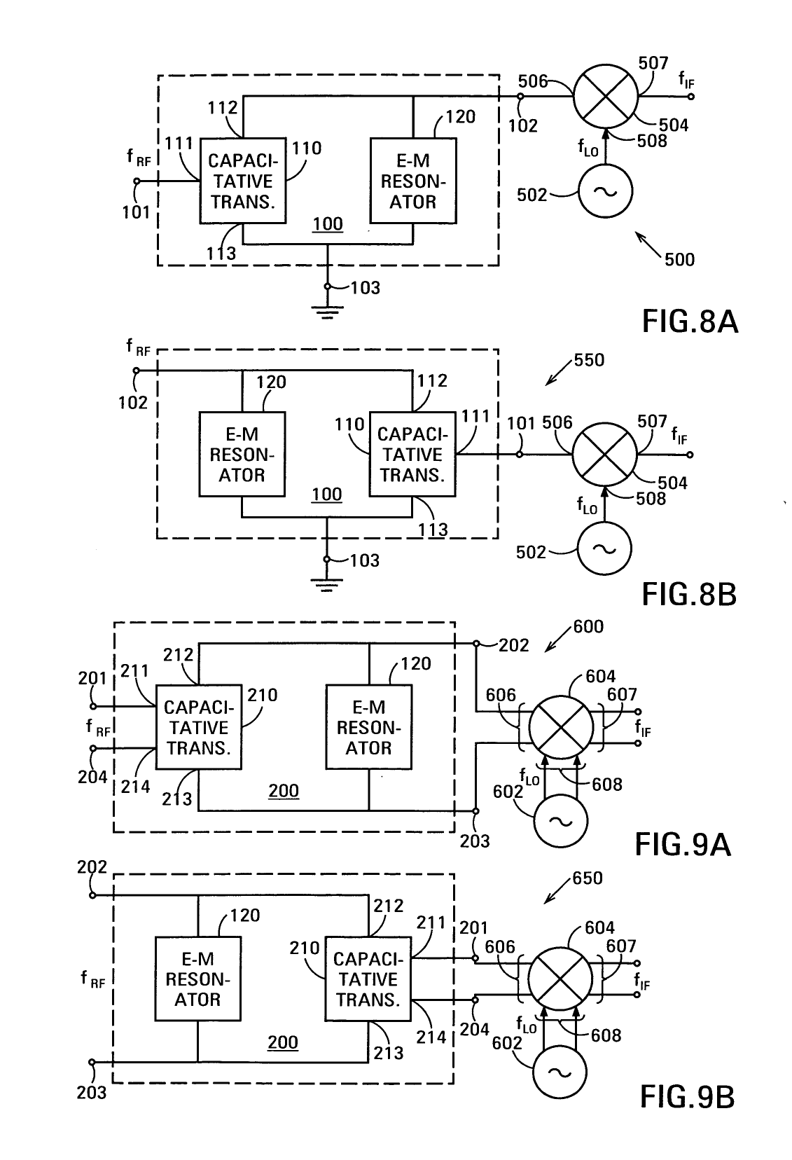

FIG. 8A is a schematic drawing showing an example of an unbalanced mixer 500 in accordance with an embodiment of the invention. Unbalanced mixer 500 is composed of unbalanced frequency-selective transformer 100 in accordance with an embodiment of the invention, a local oscillator 502 and a mixing circuit 504. Mixing circuit 504 has an RF port 506, an IF port 507 and a local oscillator port 508. Local oscillator port 508 is connected to the output of local oscillator 502.

In this embodiment, terminal 101, terminal 102 and terminal 103 of unbalanced frequency-selective transformer 100 are connected as follows. Terminal 101 is connected to the first port 111 of capacitative transformer 110 and provides the RF terminal of mixer 500. Hence, the RF terminal of mixer 500 will be referred to as RF terminal 101. Terminal 102 is connected to the second port 112 of capacitative transformer 110 and to the RF port 506 of mixing circuit 504. Terminal 103 is connected to the third port 113 of capacitative transformer 110 and to signal ground. The IF port 507 of mixing circuit 504 provides the IF terminal of mixer 500. Hence, the IF terminal of mixer 500 will be referred to as IF terminal 507

Unbalanced mixer 500 is bidirectional. In a downconverter, such as that found in a receiver, an RF signal is received at RF terminal 101 and an IF signal is output at IF terminal 507 at a frequency less that that of the RF signal. In an upconverter, such as that found in a transmitter, an IF signal is received at IF terminal 507 and an RF signal is output at RF terminal 101 at a frequency greater that that of the IF signal.

With the connections just described, frequency-selective transformer 100 provides a step up in impedance between RF terminal 101 and the RF port 506 of mixing circuit 504 and a step down in impedance between the RF port 506 of mixing circuit 504 and RF terminal 101.

FIG. 8B is a schematic drawing showing an example of an unbalanced mixer 550 in accordance with an embodiment of the invention. Unbalanced mixer 550 is composed of unbalanced frequency-selective transformer 100 in accordance with an embodiment of the invention, local oscillator 502 and mixing circuit 504, as described above. Mixing circuit 504 has an RF port 506, an IF port 507 and a local oscillator port 508. Local oscillator port 508 is connected to the output of local oscillator 502.

In this embodiment, terminal 101, terminal 102 and terminal 103 of unbalanced frequency-selective transformer 100 are connected as follows. Terminal 101 is connected to the first port 111 of capacitative transformer 110 and to the RF port 506 of mixing circuit 504. Terminal 102 is connected to the second port 112 of capacitative transformer 110 and provides the RF terminal of mixer 550. Hence, the RF terminal of mixer 550 will be referred to as RF terminal 102. Terminal 103 is connected to the third port 113 of capacitative transformer 110 and to signal ground. IF port 507 of mixing circuit 504 provides the IF terminal of mixer 550. Hence, the IF terminal of mixer 550 will be referred to as IF terminal 507.

Unbalanced mixer 550 is bidirectional. In a downconverter, such as that found in a receiver, an RF signal is received at RF terminal 102 and an IF signal is output at IF terminal 507 at a frequency less that that of the RF signal. In an upconverter, such as that found in a transmitter, an IF signal is received at IF terminal 507 and an RF signal is output at RF terminal 102 at a frequency greater that that of the IF signal.

With the connections just described, frequency-selective transformer 100 provides a step down in impedance between RF terminal 102 and the RF port 506 of mixing circuit 504 and a step up in impedance between the RF port 506 of mixing circuit 504 and RF terminal 102.

In unbalanced mixers 500 and 550, frequency-selective transformer 100 subjects an RF spectrum received at first terminal 101 or second terminal 102 to impedance transformation and additionally subjects the RF spectrum to frequency selection such that frequency-selective transformer 100 passes with a step up in voltage the portion of the RF spectrum in its pass band, attenuates the portion of the RF spectrum outside its pass band and significantly attenuates the portion of the RF spectrum in its stop band.

In unbalanced mixers 500 and 550, the frequency f_{LO} of the local oscillator signal generated by local oscillator 502, the frequency f_{RF} of the wanted RF signal at RF terminal 101 or the wanted RF signal at RF terminal 102 and the frequency f_{IF} of the IF signal at IF terminal 507 are related as follows: f_{RF}=|f_{LO}+f_{IF}|. Frequency-selective transformer 100 is configured such that the frequency f_{RF} of the RF signal is within its pass band and the frequency f_{IM} (f_{IM}=|f_{LO}−f_{IF}|) of the image signal is within its stop band. Optimum results are obtained when the frequencies of the pass band and the stop band are nominally aligned with the frequencies of the wanted RF signal and the image signal, respectively. The frequency of the local oscillator is set mid-way between the nominal frequencies of the pass band and the stop band of frequency-selective transformer 100. The intermediate frequency is nominally one half of the frequency difference between the frequencies of the pass band and the stop band. Since the electromechanical resonator that forms part of frequency-selective transformer 100 allows the pass band and the stop band to be closely spaced in frequency, the frequency f_{IF} of the IF signal can be relatively low. In the example shown in FIG. 3B, in which the frequency of the pass band is about 2.13 GHz, the frequency f_{P} of the pass band is about 16 MHz greater than the frequency f_{S} of the stop band, which corresponds to the IF signal having a frequency f_{IF} of about 8 MHz, a relatively low frequency.

FIG. 9A is a schematic drawing showing an example of a balanced mixer 600 in accordance with an embodiment of the invention. Balanced mixer 600 is composed of balanced frequency-selective transformer 200 in accordance with an embodiment of the invention, a local oscillator 602 and a mixing circuit 604. Mixing circuit 604 has an RF port 606, an IF port 607 and a local oscillator port 608, all of which are balanced in the example shown. In other examples, not all of the ports are balanced. Local oscillator port 608 is connected to the output of local oscillator 602.

In this embodiment, terminal 201, terminal 202, terminal 203 and terminal 204 of balanced frequency-selective transformer 200 are connected as follows. Terminal 201 and Terminal 204 are connected to the first port 211 and the fourth port 214, respectively, of capacitative transformer 210, and additionally provide the RF terminals of mixer 600. Hence, the RF terminals of mixer 600 will be referred to as RF terminals 201/204. Terminal 202 and terminal 203 are connected to the second port 212 and the third port 213, respectively, of capacitative transformer 210 and to electromagnetic resonator 120, and are additionally connected to the RF port 606 of mixing circuit 604. IF port 607 of mixing circuit 604 provides the IF terminals of mixer 600. Hence, the IF terminals of mixer 600 will be referred to as IF terminals 607

Balanced mixer 600 is bidirectional. In a downconverter, such as that found in a receiver, an RF signal is received at RF terminals 201/204 and an IF signal is output at IF terminals 607 at a frequency less that that of the RF signal. In an upconverter, such as that found in a transmitter, an IF signal is received at IF terminals 607 and an RF signal is output at RF terminals 201/204 at a frequency greater that that of the IF signal.

With the connections just described, frequency-selective transformer 200 provides a step up in impedance between RF terminals 201/204 and the RF port 606 of mixing circuit 604 and a step down in impedance between the RF port 606 of mixing circuit 604 and RF terminals 201/204.

FIG. 9B is a schematic drawing showing an example of a balanced mixer 650 in accordance with an embodiment of the invention. Balanced mixer 620 is composed of balanced frequency-selective transformer 200 in accordance with an embodiment of the invention, local oscillator 602 and mixing circuit 604, as described above. Mixing circuit 604 has an RF port 606, an IF port 607 and a local oscillator port 608, all of which are balanced in the example shown. In other examples, not all of the ports are balanced. Local oscillator port 608 is connected to the output of local oscillator 602.

In this embodiment, terminal 201, terminal 202, terminal 203 and terminal 204 of balanced frequency-selective transformer 200 are connected as follows. Terminal 201 and terminal 204 are connected to the first port 211 and the fourth port 214, respectively, of capacitative transformer 210 and are additionally connected to the RF port 606 of mixing circuit 604. Terminal 202 and terminal 203 are connected to the second port 212 and the third port 213, respectively, of capacitative transformer 210 and to electromagnetic resonator 120, and additionally provide the RF terminals of mixer 650. Hence, the RF terminals of mixer 650 will be referred to as RF terminals 202/203. IF port 607 of mixing circuit 604 provides the IF terminals of mixer 650. Hence, the IF terminals of mixer 650 will be referred to as IF terminals 607

Balanced mixer 650 is bidirectional. In a downconverter, such as that found in a receiver, an RF signal is received at RF terminals 202/203 and an IF signal is output at IF terminals 607 at a frequency less that that of the RF signal. In an upconverter, such as that found in a transmitter, an IF signal is received at IF terminals 607 and an RF signal is output at RF terminals 202/203 at a frequency greater that that of the IF signal.

With the connections just described, frequency-selective transformer 200 provides a step down in impedance between RF terminals 202/203 and the RF port 606 of mixing circuit 604 and a step up in impedance between the RF port 606 of mixing circuit 604 and RF terminals 202/203.

In balanced mixers 600 and 650, frequency-selective transformer 200 subjects an RF spectrum received at terminal 201 and terminal 204, or at terminal 202 and terminal 203 to impedance transformation and additionally subjects the RF spectrum to frequency selection such that frequency-selective transformer passes with a step up in voltage the portion of the RF spectrum in its pass band, attenuates the portion of the RF spectrum outside its pass band and significantly attenuates the portion of the RF spectrum in its stop band.

In balanced mixers 600 and 650, the frequency f_{Lo} of the local oscillator signal generated by local oscillator 602, the frequency f_{RF} of the wanted RF signal at RF terminals 201/204 or the wanted RF signal at RF terminals 202/203, and the frequency f_{IF} of the IF signal at IF terminals 607 are related as follows: f_{RF}=|f_{LO}+f_{IF}|. Frequency-selective transformer 200 is configured such that the frequency f_{RF} of the RF signal is within its pass band and the frequency f_{IM} of the image signal (f_{IM}=|f_{LO}−f_{IF}|) is within its stop band. Optimum results are obtained when the frequencies of the pass band and the stop band are nominally aligned with the frequencies of the wanted RF signal and the image signal, respectively. The frequency of the local oscillator is set mid-way between the nominal frequencies of the pass band and the stop band of frequency-selective transformer 200. The intermediate frequency is nominally one half of the frequency difference between the center frequencies of the pass band and the stop band. Since the electromechanical resonator that forms part of frequency-selective transformer 200 allows the pass band and the stop band to be closely spaced in frequency, the frequency f_{IF} of the IF signal can be relatively low, as described above.

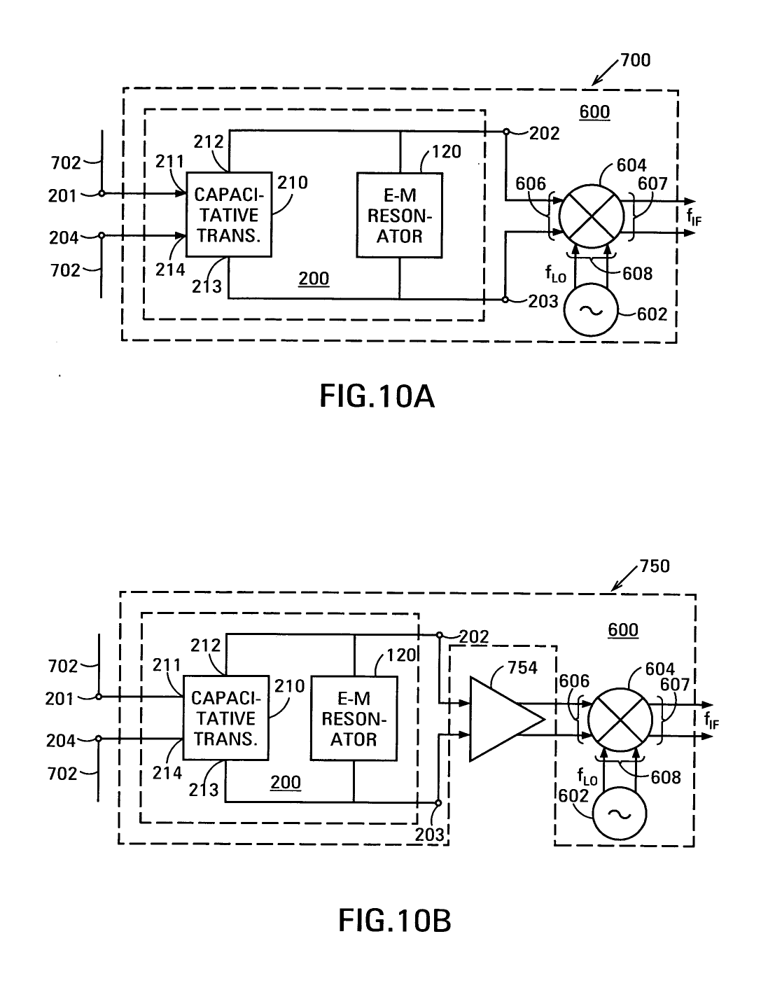

A number of examples of receiver front ends and transmitter output stages incorporating the embodiments of balanced mixers 600 and 650 described above with reference to FIGS. 9A and 9B, respectively, will now be described with reference to FIGS. 10-13. The examples described below can easily be modified to incorporate corresponding embodiments of unbalanced mixers 500 and 550 described above with reference to FIGS. 8A and 8B. Relevant points of difference between the balanced and unbalanced embodiments will be described as they arise.

FIG. 10A is a schematic drawing showing an example of the front end of a receiver 700 incorporating an embodiment of mixer 600 described above with reference to FIG. 9A. Receiver 700 comprises mixer 600 and an antenna 702. The RF terminals 201/204 of mixer 600 are connected to antenna 702. Mixer 600 provides an IF signal at IF port 607.

In receiver 700, mixer 600 receives an RF spectrum at its RF terminals 201/204 from antenna 702. The RF spectrum includes a wanted RF signal at a frequency f_{RF} and may additionally include an image signal at a frequency f_{IM} that differs from frequency f_{RF} by twice the IF frequency f_{IF}. In mixer 600, frequency-selective transformer 200 subjects the RF spectrum received at RF terminals 201/204 to a step up in impedance, a step up in voltage and frequency-selective filtering. The filtering selects the wanted RF signal from the RF spectrum, and additionally significantly attenuates any image signal present in the RF spectrum. Frequency-selective transformer 200 provides the wanted RF signal at frequency f_{RF} to the RF port 606 of mixing circuit 604. Mixing circuit 604 additionally receives the local oscillator signal at frequency f_{Lo} at its local oscillator port 608. Mixing circuit 604 mixes the signals received at its RF and local oscillator ports to generate an IF signal at a frequency f_{IF}=|f_{RF}−f_{LO}|. Since frequency-selective transformer 200 significantly attenuates any image signal present in the RF spectrum received by antenna 702, the contribution of such image signal to the IF signal is negligible. Mixing circuit 604 outputs the IF signal from IF port 607 to the IF portion (not shown) of receiver 700.

In mixer 600, frequency-selective transformer 200 provides a step up in impedance and a step up in voltage between RF terminals 201/204 and the RF port 606 of mixing circuit 604. The step up in impedance provided by frequency-selective transformer 200 better matches the output impedance of antenna 702 (typically 50 Ω to 300 Ω) to the greater input impedance of RF port 606. Additionally, the step up in voltage provided by frequency-selective transformer 200 increases the signal level at the RF port 606 of mixing circuit 604 and, hence, the signal-to-noise ratio of the IF signal output at IF port 607. Additionally, frequency-selective transformer 200 is configured as described above to provide significant attenuation at the frequency of the image signal so that receiver 700 has good image rejection performance.

In an embodiment of receiver 700 incorporating an embodiment of unbalanced mixer 500 described above with reference to FIG. 8A, the antenna is connected to the RF terminal 101 of mixer 500.

In many applications, the step-up in voltage provided by frequency-selective transformer 200 is sufficient to allow receiver 700 to meet its sensitivity specifications without the need for amplification ahead of mixing circuit 604. In applications that require greater sensitivity, a low-noise amplifier may be incorporated into the receiver front-end. FIG. 10B is a schematic drawing showing an example of a receiver 750 whose front end incorporates a low-noise amplifier.

Receiver 750 comprises mixer 600, antenna 702 and a low-noise amplifier 752. In receiver 750, the RF terminals 201/204 of mixer 600 are connected to antenna 702 and mixer 600 provides an IF signal at IF port 607, as described above. In the example shown, low noise amplifier 754 is interposed between frequency-selective transformer 200 and the RF port 606 of mixing circuit 604. Specifically, low-noise amplifier 754 has its inputs connected to terminals 202/203 of frequency-selective transformer 200 and its outputs connected to the RF port 606 of mixing circuit 604. Thus, in this embodiment, low-noise amplifier 754 couples RF port 606 to the second port 212 and the third port 213 of capacitative transformer 210 that forms part of frequency-selective transformer 200.

The step up in impedance provided by frequency-selective transformer 200 better matches the output impedance of antenna 702 to the greater input impedance of low noise amplifier 754. Additionally, the step up in voltage provided by frequency-selective transformer 200 increases the signal level at the input of low-noise amplifier 754 and, hence, increases the signal-to-noise ratio of the amplified RF signal output by low-noise amplifier 754 and the signal-to-noise ratio of the IF signal output at IF port 607. The attenuation of the image signal by frequency-selective transformer 200 additionally reduces the possibility of such signal overloading low-noise amplifier 754.

Low-noise amplifier 754 may alternatively be interposed between antenna 702 and the RF terminals 201/204 of mixer 600. However, some of the above-described performance advantages are lost with such alternative location of low-noise amplifier 754.

In an embodiment of receiver 750 incorporating an embodiment of unbalanced mixer 500 described above with reference to FIG. 8B, the antenna is connected to the RF terminal 101 of mixer 500, the input of the low-noise amplifier is connected to terminal 102 of frequency-selective transformer 100 and the output of the low-noise amplifier is connected to the IF port 506 of mixing circuit 504.

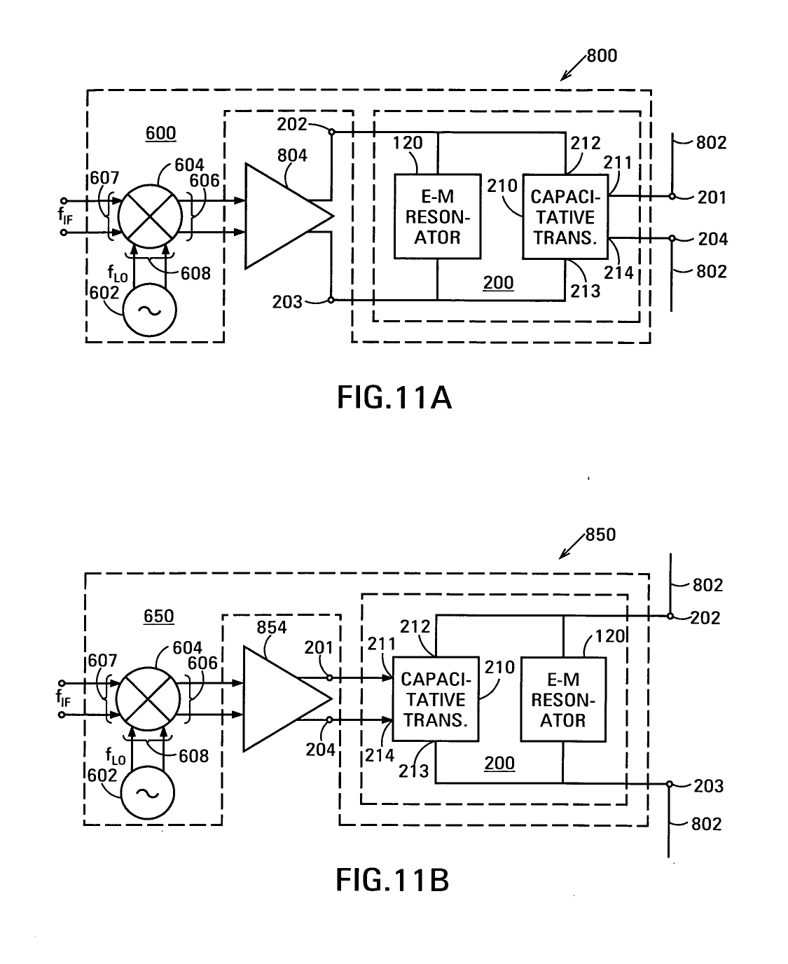

FIG. 11A is a schematic drawing showing an example of the output stage of a transmitter 800 incorporating an embodiment of mixer 600 described above with reference to FIG. 9A. Transmitter 800 comprises mixer 600, an antenna 802 and a power amplifier 804. Transmitter 800 is a relatively low power transmitter in which power amplifier 804 has an output impedance substantially greater than the input impedance of antenna 802.

In transmitter 800, mixer 600 receives an IF signal at the IF port 607 of mixing circuit 604. Power amplifier 804 is interposed between the RF port 606 of mixing circuit 604 and frequency-selective transformer 200. Specifically, power amplifier 802 has its inputs connected to RF port 607 and its outputs connected to terminals 202/203 of frequency-selective transformer 200. Thus, in this embodiment, power amplifier 804 couples RF port 606 to the second port 212 and the third port 213 of capacitative transformer 210 that forms part of frequency-selective transformer 200. The RF terminals 201/204 of mixer 600 are connected to antenna 802.

In another embodiment, the RF port 606 of mixing circuit 604 provides sufficient power to drive antenna 802 at the maximum rated power output of transmitter 800. In this case, power amplifier 804 is omitted and RF port 606 is connected directly to terminals 202/203 of frequency-selective transformer 200.

In mixer 600, mixing circuit 604 receives the IF signal at a frequency f_{IF} at its IF port 607 and additionally receives the local oscillator signal at a frequency f_{LO} at its local oscillator port 608. Mixing circuit 604 mixes the signals received at its IF and local oscillator ports to generate a wanted RF signal at a frequency f_{RF}=|f_{LO}+f_{IF}| and an image signal at a frequency f_{IM}=|f_{LO-f}_{IF}|. Power amplifier 804 amplifies the RF signal and the image signal and provides them to frequency-selective transformer 200. At the frequency of the wanted RF signal, frequency-selective transformer 200 provides a step down in impedance and a step down in voltage between its terminals 202/203 and its terminals 201/204, which provide the RF terminals 201/204 of mixer 600. The RF terminals 201/204 of mixer 600 are connected to antenna 802. The step down in impedance provided by frequency-selective transformer 200 better matches the output impedance of power amplifier 804 to the smaller input impedance (typically 50 Ω to 300 Ω) of antenna 802.

Frequency-selective transformer 200 is configured as described above to provide significant attenuation at the frequency of the image signal. As a result, the level of the image signal transmitted by transmitter 800 is acceptably low.

In an embodiment of transmitter 800 incorporating an embodiment of unbalanced mixer 500 described above with reference to FIG. 8A, the output of the power amplifier is connected to terminal 102 of frequency-selective transformer 100 and the antenna is connected to the RF terminal 101 of mixer 500. In an embodiment incorporating mixer 500 in which the RF port 506 of mixing circuit 504 provides sufficient power to drive antenna 802 at the maximum rated power output of the transmitter, the power amplifier is omitted and RF port 506 is connected directly to terminal 102 of frequency-selective transformer 100.

FIG. 11B is a schematic drawing showing an example of the output stage of a transmitter 850 incorporating an embodiment of mixer 650 described above with reference to FIG. 9B.

Transmitter 850 comprises mixer 650, antenna 802 and a power amplifier 854. Transmitter 800 is a relatively high power transmitter in which power amplifier 854 has an output impedance substantially smaller than the input impedance of antenna 802.

In transmitter 850, mixer 650 receives an IF signal at the IF port 607 of mixing circuit 604. Power amplifier 854 is interposed between the RF port 606 of mixing circuit 604 and frequency-selective transformer 200. Specifically, power amplifier 804 has its inputs connected to RF port 607 and its outputs connected to terminals 201/204 of frequency-selective transformer 200. Thus, in this embodiment, power amplifier 854 couples RF port 606 to the first port 211 and the fourth port 214 of capacitative transformer 210 that forms part of frequency-selective transformer 200. The RF terminals 202/203 of mixer 650 are connected to antenna 802.

In mixer 650, mixing circuit 604 receives the IF signal at a frequency f_{IF} at its IF port 607 and additionally receives the local oscillator signal at a frequency fLo at its local oscillator port 608. Mixing circuit 604 mixes the signals received at its IF and local oscillator ports to generate a wanted RF signal at a frequency f_{RF}=|f_{LO}+f_{IF}| and an image signal at a frequency f_{IM}=|f_{LO}−f_{IF}|. Power amplifier 854 amplifies the RF signal and the image signal and provides them to frequency-selective transformer 200. At the frequency of the wanted RF signal, frequency-selective transformer 200 provides a step up in impedance and a step up in voltage between its terminals 201/204 and its terminals 202/203, which provide the RF terminals 202/203 of mixer 650. Mixer 650 provides the RF signal to antenna 802 via RF terminals 202/203. The step up in impedance provided by frequency-selective transformer 200 better matches the output impedance of power amplifier 854 to the greater input impedance of antenna 802 (typically 50 Ω to 300 Ω). Additionally, the step up in voltage provided by frequency-selective transformer 200 increases the voltage swing driving antenna 802 for a given voltage swing at the output of power amplifier 854.

Frequency-selective transformer 200 is configured as described above to provide significant attenuation at the frequency of the image signal. As a result, the level of the image signal transmitted by transmitter 850 is acceptably low.

In an embodiment of transmitter 850 incorporating an embodiment of unbalanced mixer 550 described above with reference to FIG. 8B, the output of the power amplifier is connected to terminal 101 of frequency-selective transformer 100 and the antenna is connected to the RF terminal 102 of mixer 550.

This disclosure describes the invention in detail using illustrative embodiments. However, the invention defined by the appended claims is not limited to the precise embodiments described.

I claim:

1. A frequency-selective transformer, comprising:
a capacitative transformer comprising a first port, a second port, and a third port; and
an electromechanical resonator connected between the second port and the third port of the capacitative transformer, the electromechanical resonator having a series resonance and a parallel resonance, the resonances closely spaced in frequency.

2. The frequency-selective transformer of claim 1, in which the series resonance and the parallel resonance differ in frequency by a predetermined frequency difference.

3. The frequency-selective transformer of claim 1, in which the capacitative transformer comprises:
a first capacitative element connected between the first port and the second port; and
a second capacitative element connected between the first port and the third port.

4. The frequency-selective transformer of claim 3, in which at least one of the capacitative elements comprises a capacitor.

5. The frequency-selective transformer of claim 3, in which at least one of the capacitative elements comprises a bulk acoustic wave (BAW) resonator.

6. The frequency-selective transformer of claim 3, in which the third port is connected to signal ground.

7. The frequency-selective transformer of claim 1, in which the capacitative transformer additionally comprises:
a fourth port;
a first capacitative element connected between the first port and the second port;
a second capacitative element connected between the first port and the fourth port; and
a third capacitative element connected between the fourth port and the third port.

8. The frequency-selective transformer of claim 7, in which at least one of the capacitative elements comprises a capacitor.

9. The frequency-selective transformer of claim 7, in which at least one of the capacitative elements comprises a bulk acoustic wave (BAW) resonator.

10. The frequency-selective transformer of claim 1, additionally comprising a capacitor connected in parallel with the electromagnetic resonator.

11. The frequency-selective transformer of claim 9, in which the capacitor is a variable capacitor.

12. The frequency-selective transformer of claim 1, in which the resonator comprises a bulk acoustic wave (BAW) resonator.

13. The frequency-selective transformer of claim 12, in which the bulk acoustic wave resonator comprises a film bulk acoustic resonator (FBAR).

14. The frequency-selective transformer of claim 1, in which:
the electromagnetic resonator is a first electromagnetic resonator; and
the frequency-selective transformer additionally comprises:
a second electromagnetic resonator having a parallel resonance differing in frequency from the parallel resonance of the first electromagnetic resonator, and
a switching element operable to select one of the first electromagnetic resonator and the second electromagnetic resonator.

15. An unbalanced mixer, comprising:
a local oscillator;
a mixing circuit comprising a radio-frequency (RF) port, an intermediate frequency (IF) port and a local oscillator (LO) port, the LO port connected to the local oscillator; and
a frequency-selective transformer, comprising:
a capacitative transformer comprising a first port, a second port and a third port, the capacitative transformer coupled to the RF port of the mixing circuit via one of the first port and the second port, and
an electromechanical resonator connected between the second port and the third port of the capacitative transformer, the electromechanical resonator having a series resonance and a parallel resonance, the resonances closely spaced in frequency.

16. The mixer of claim 15, in which the capacitative transformer comprises:
a first capacitative element connected between the first port and the second port; and
a second capacitative element connected between the first port and the third port.

17. The mixer of claim 16, in which at least one of the capacitative elements comprises a bulk acoustic wave (BAW) resonator.

18. The mixer of claim 15, in which:
the series resonance and the parallel resonance have respective resonant frequencies that differ by a predetermined frequency difference;
the local oscillator has a frequency mid-way between the resonant frequencies; and at the IF port of the mixing circuit, an IF signal exists at a frequency equal to one-half of the predetermined frequency difference.

19. A receiver, comprising the unbalanced mixer of claim 15.

20. The receiver of claim 19, in which the capacitative transformer comprises:
a first capacitative element connected between the first port and the second port; and a second capacitative element connected between the first port and the third port.

21. The receiver of claim 18, in which:
the receiver additionally comprises an antenna input coupled to the first port; and the RF port of the mixing circuit is coupled to the second port.

22. The receiver of claim 21, in which:
the series resonance and the parallel resonance of the resonator have respective resonant frequencies that differ by a predetermined frequency difference;
the local oscillator has a frequency mid-way between the resonant frequencies; and
at the IF port of the mixing circuit, an IF signal exists at a frequency equal to one-half of the predetermined frequency difference.

23. A transmitter, comprising the unbalanced mixer of claim 15.

24. The transmitter of claim 23, in which the capacitative transformer comprises:
a first capacitative element connected between the first port and the second port; and
a second capacitative element connected between the first port and the third port.

25. The transmitter of claim 23, in which the IF port is connected to receive an intermediate-frequency signal.

26. The transmitter of claim 25, in which:
the series resonance and the parallel resonance have respective resonant frequencies that differ by a predetermined frequency difference;
the local oscillator generates a local oscillator signal at a frequency mid-way between the resonant frequencies; and
at the RF port of the mixing circuit, an RF signal exists differing in frequency from the local oscillator signal by one-half of the predetermined frequency difference.

27. A balanced mixer, comprising:
a local oscillator;
a mixing circuit comprising a radio-frequency (RF) port, an intermediate frequency (IF) port and a local oscillator (LO) port, the LO port connected to the local oscillator; and
a frequency-selective transformer, comprising:
a capacitative transformer comprising a first port, a second port, a third port and a fourth port, the capacitative transformer coupled to the RF port of the mixing circuit via one of (a) the first port and the fourth port, and (b) the second port and the third port;
an electromechanical resonator connected between the second port and the third port of the capacitative transformer, the resonator having a series resonance and a parallel resonance, the resonances closely spaced in frequency.

28. The mixer of claim 27, in which the capacitative transformer additionally comprises:
a first capacitative element connected between the first port and the second port;
a second capacitative element connected between the first port and the fourth port; and
a third capacitative element connected between the fourth port and the third port.

29. The mixer of claim 28, in which at least one of the capacitative elements comprises a bulk acoustic wave (BAW) resonator.

30. The mixer of claim 27, in which:
the series resonance and the parallel resonance have respective resonant frequencies that differ by a predetermined frequency difference;
the local oscillator has a frequency mid-way between the resonant frequencies; and
at the IF port of the mixing circuit, an IF signal exists at a frequency equal to one-half of the predetermined frequency difference.

31. A receiver, comprising the balanced mixer of claim 27.

32. The receiver of claim 31, in which the capacitative transformer additionally comprises:
a first capacitative element connected between the first port and the second port;
a second capacitative element connected between the first port and the fourth port; and
third capacitative element connected between the fourth port and the third port.

33. The receiver of claim 31, in which:
the receiver additionally comprises an antenna input coupled to the first port and the fourth port; and
the RF port of the mixing circuit is coupled to the second port and the third port.

34. The receiver of claim 33, in which:
the series resonance and the parallel resonance of the resonator have respective resonant frequencies that differ by a predetermined frequency difference;
the local oscillator has a frequency mid-way between the resonant frequencies; and
at the IF port of the mixing circuit, an IF signal exists at an intermediate frequency equal to one-half of the predetermined frequency difference.

35. A transmitter, comprising the balanced mixer of claim 27.

36. The transmitter of claim 35, in which the capacitative transformer additionally comprises:
a first capacitative element connected between the first port and the second port;
a second capacitative element connected between the first port and the fourth port; and
a third capacitative element connected between the fourth port and the third port.

37. The transmitter of claim 35, in which the IF port of the mixing circuit is connected to receive an intermediate-frequency signal.

38. The transmitter of claim 37, in which:
the series resonance and the parallel resonance have respective resonant frequencies that differ by a predetermined frequency difference;
the local oscillator generates a local oscillator signal at a frequency mid-way between the resonant frequencies; and
at the RF port of the mixing circuit, an RF signal exists differing in frequency from the local oscillator signal by one-half of the predetermined frequency difference.
